(19) United States
(12) Patent Application Publication
(10) Pub. No.: US 2025/0029879 A1
(43) Pub. Date: Jan. 23, 2025

(54) SEMICONDUCTOR PACKAGE

(71) Applicant: SAMSUNG ELECTRONICS CO., LTD., Suwon-si (KR)

(72) Inventors: Dongkuk Lee, Suwon-si (KR); Yeongseon Kim, Suwon-si (KR)

(21) Appl. No.: 18/765,816

(22) Filed: Jul. 8, 2024

(30) Foreign Application Priority Data
Jul. 20, 2023 (KR) 10-2023-0094616

(51) Int. Cl. H01L 21/66; H01L 23/00; H01L 23/48; H01L 25/065

(52) U.S. Cl. CPC H01L 22/32; H01L 23/481; H01L 24/05; H01L 25/0657; H01L 2224/05554; H01L 2225/06541; H01L 2225/06596; H01L 2924/1431

(57) ABSTRACT

Disclosed is a semiconductor package comprising a first semiconductor chip and a second semiconductor chip on the first semiconductor chip. The first semiconductor chip may include an upper bonding pad, an upper test pad, and an upper dielectric layer that surrounds the upper bonding pad and the upper test pad. The second semiconductor chip includes a lower bonding pad in contact with the upper bonding pad, a lower test pad in contact with the upper test pad, and a lower dielectric layer that surrounds the lower bonding pad and the lower test pad.

### CROSS-REFERENCE TO RELATED APPLICATION

This U.S. nonprovisional application claims priority under 35 U.S.C § 119 to Korean Patent Application No. 10-2023-0094616, filed on Jul. 20, 2023, in the Korean Intellectual Property Office, the disclosure of which is hereby incorporated by reference in its entirety.

### BACKGROUND

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies have been conducted to improve reliability and durability of semiconductor packages.

### SUMMARY

The subject matter of the present disclosure generally relates to a semiconductor package with improved electrical properties and increased reliability.

According to some implementations of the present disclosure, a semiconductor package includes: a first semiconductor chip; and a second semiconductor chip on the first semiconductor chip. The first semiconductor chip may include: an upper bonding pad; an upper test pad; and an upper dielectric layer that surrounds the upper bonding pad and the upper test pad. The second semiconductor chip may include: a lower bonding pad in contact with the upper bonding pad; a lower test pad in contact with the upper test pad; and a lower dielectric layer that surrounds the lower bonding pad and the lower test pad. The upper test pad may include: a first overlapping portion that overlaps the lower test pad; and a plurality of second overlapping portions that overlap the lower dielectric layer. The first overlapping portion may be between the second overlapping portions. The lower test pad may include: a third overlapping portion that overlaps the first overlapping portion of the upper test pad; and a plurality of fourth overlapping portions that overlap the upper dielectric layer. The third overlapping portion may be between the fourth overlapping portions.

According to some implementations of the present disclosure, a semiconductor package includes: a first semiconductor chip; and a second semiconductor chip on the first semiconductor chip. The first semiconductor chip may include an upper bonding pad and an upper test pad. The second semiconductor chip may include: a lower bonding pad in contact with the upper bonding pad; and a lower test pad in contact with the upper test pad. The upper test pad may include: a plurality of first long sidewalls that extend in parallel to each other; and a plurality of first short sidewalls that extend in parallel to each other. The lower test pad may include: a plurality of second long sidewalls that extend in parallel to each other; and a plurality of second short sidewalls that extend in parallel to each other. The first short sidewalls and the second short sidewalls may be shorter than the first long sidewalls and the second long sidewalls.

According to some implementations of the present disclosure, a semiconductor package includes: a first semiconductor chip; and a second semiconductor chip on the first semiconductor chip. The first semiconductor chip may include: a first lower dielectric layer; a first wiring structure on the first lower dielectric layer; a first substrate on the first wiring structure; a through via that penetrates the first substrate; an upper dielectric layer on the first substrate; and an upper bonding pad and an upper test pad that are surrounded by the upper dielectric layer. The second semiconductor chip may include: a lower bonding pad in contact with the upper bonding pad; a lower test pad in contact with the upper test pad; a second lower dielectric layer that surrounds the lower bonding pad and the lower test pad; a second wiring structure on the second lower dielectric layer; and a second substrate on the second wiring structure. The upper test pad may include: a first overlapping portion in contact with the lower test pad; and a plurality of second overlapping portions in contact with the second lower dielectric layer. A sidewall of the first overlapping portion may be coplanar with sidewalls of the second overlapping portions.

### BRIEF DESCRIPTION OF DRAWINGS

FIG. 1A illustrates a cross-sectional view showing a semiconductor package according to some implementations.

FIG. 1B illustrates an enlarged view showing section E1 of FIG. 1A.

FIG. 1C illustrates a plan view of a first semiconductor chip viewed from a bonding section between first and second semiconductor chips of FIG. 1A.

FIG. 1D illustrates a plan view of a second semiconductor chip viewed from a bonding section between first and second semiconductor chips of FIG. 1A.

FIG. 1E illustrates a plan view showing an upper test pad of a first semiconductor chip and its bonded lower test pad of a second semiconductor chip.

FIGS. 2A and 2B illustrate plan views of semiconductor chips viewed from a bonding section between semiconductor chips of a semiconductor package according to some implementations.

FIGS. 3A and 3B illustrate plan views of semiconductor chips viewed from a bonding section between semiconductor chips of a semiconductor package according to some implementations.

FIG. 4 illustrates a cross-sectional view showing a semiconductor package according to some implementations.

FIG. 5 illustrates a cross-sectional view showing a semiconductor package according to some implementations.

FIG. 6 illustrates a cross-sectional view showing a semiconductor package according to some implementations.

### DETAILED DESCRIPTION

The following will describe in detail a semiconductor package and its fabrication method according to some implementations of the present disclosure in conjunction with the accompanying drawings.

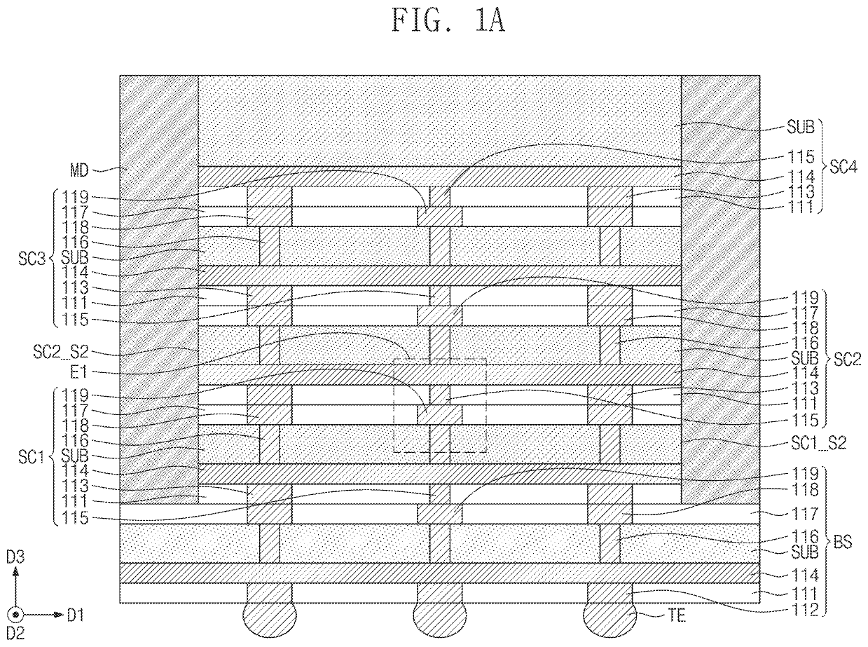

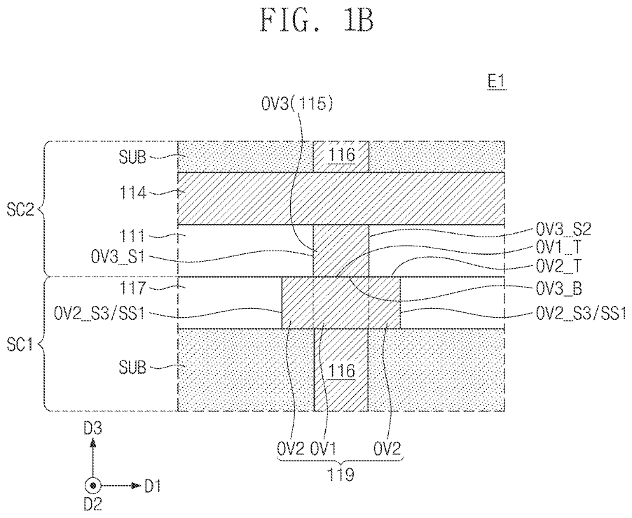

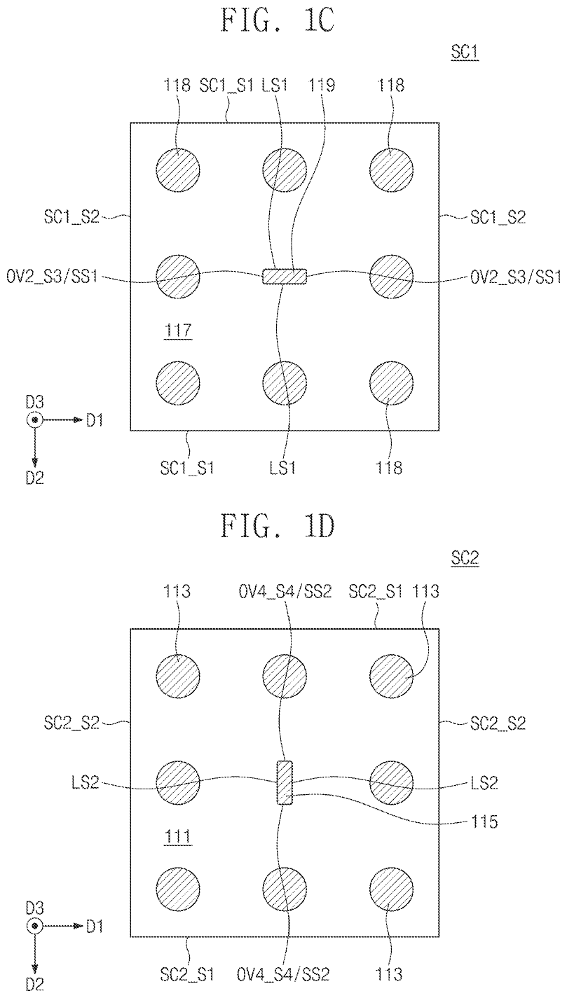

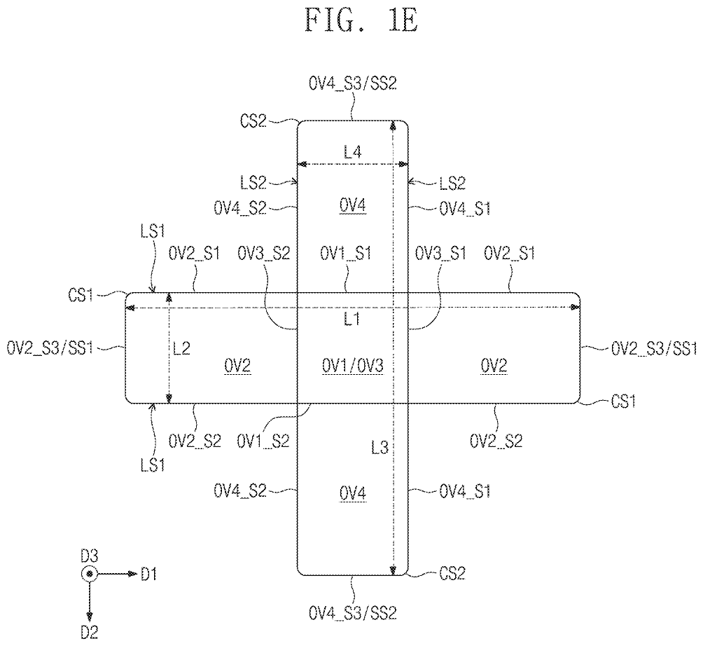

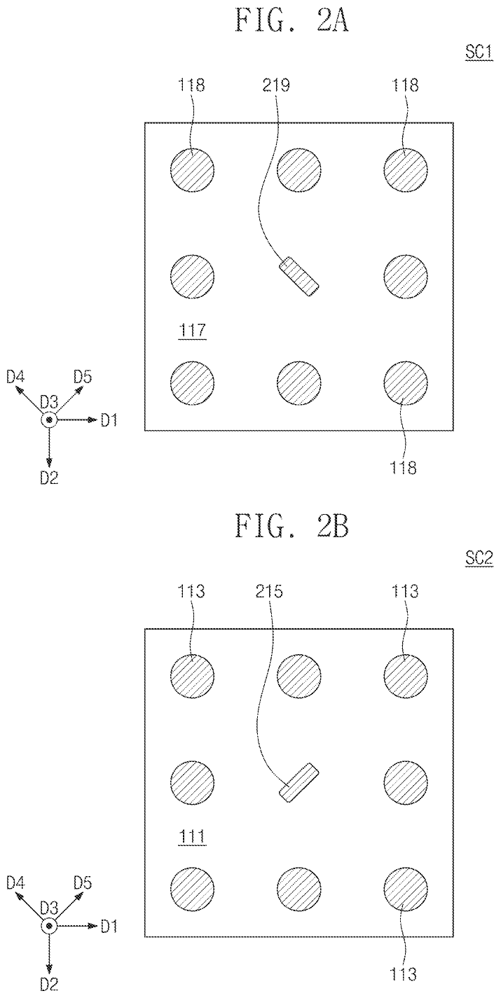

FIG. 1A illustrates a cross-sectional view showing a semiconductor package according to some implementations. FIG. 1B illustrates an enlarged view showing section E1 of FIG. 1A. FIG. 1C illustrates a plan view of a first semiconductor chip viewed from a bonding section between first and second semiconductor chips of FIG. 1A. FIG. 1D illustrates a plan view of a second semiconductor chip viewed from a bonding section between first and second semiconductor chips of FIG. 1A. FIG. 1E illustrates a plan view showing an upper test pad of a first semiconductor chip and its bonded lower test pad of a second semiconductor chip.

Referring to FIG. 1A, a semiconductor package includes a base structure BS. The semiconductor package also includes a first semiconductor chip SC1, a second semiconductor chip SC2, a third semiconductor chip SC3, and a fourth semiconductor chip SC4 that are sequentially stacked on the base structure BS. It is illustrated that the number of the semiconductor chips SC1, SC2, SC3, and SC4 is four, but the present disclosure is not limited thereto. In some implementations, the number of the semiconductor chips SC1, SC2, SC3, and SC4 may be three or less, or five or greater. Each of the base structure BS and the first, second, third, and fourth semiconductor chips SC1, SC2, SC3, and SC4 may have a plate shape that extends along a plane defined by a first direction D and a second direction D2. The first direction D1 and the second direction D2 may intersect each other. For example, the first direction D1 and the second direction D2 may be horizontal directions that are orthogonal to each other.

A molding layer MD may be provided on the base structure BS to surround the first, second, third, and fourth semiconductor chips SC1, SC2, SC3, and SC4. The molding layer MD may include a polymeric material. For example, the molding layer MD may include an epoxy resin. Terminals TE may be provided which are connected to the base structure BS. The semiconductor package may be electrically connected through the terminals TE to an external apparatus. The terminals TE may include a conductive material.

The first semiconductor chip SC1 includes a lower dielectric layer 111, lower bonding pads 113, a lower test pad 115, a wiring structure 114, a substrate SUB, through vias 116, an upper dielectric layer 117, upper bonding pads 118, and an upper test pad 119.

The wiring structure 114 and the substrate SUB may be provided between the lower dielectric layer 111 and the upper dielectric layer 117. The lower dielectric layer 111 and the upper dielectric layer 117 may include a dielectric material. In some implementations, each of the lower dielectric layer 111 and the upper dielectric layer 117 may be a multiple layer including a plurality of dielectric layers.

The lower bonding pads 113 and the lower test pad 115 may be provided in the lower dielectric layer 111. The lower dielectric layer 111 may surround the lower bonding pads 113 and the lower test pad 115. The lower bonding pads 113 and the lower test pad 115 may penetrate in a third direction D3 through the lower dielectric layer 111. The third direction D3 may intersect the first direction D1 and the second direction D2. For example, the third direction D3 may be a vertical direction perpendicular to the first direction D1 and the second direction D2.

The upper bonding pads 118 and the upper test pad 119 may be provided in the upper dielectric layer 117. The upper dielectric layer 117 may surround the upper bonding pads 118 and the upper test pad 119. The upper bonding pads 118 and the upper test pad 119 may penetrate in the third direction D3 through the upper dielectric layer 117.

The upper bonding pads 118, the upper test pad 119, the lower bonding pads 113, and the lower test pad 115 may include a conductive material. For example, the upper bonding pads 118, the upper test pad 119, the lower bonding pads 113, and the lower test pad 115 may include copper.

The wiring structure 114 may be provided on the lower dielectric layer 111. The wiring structure 114 may be connected to the lower bonding pads 113 and the lower test pad 115. The wiring structure 114 may include a plurality of dielectric layers and a plurality of conductive structures in the dielectric layers. The conductive structure of the wiring structure 114 may include at least one selected from a conductive contact, a conductive line, and a conductive pad. The conductive structure of the wiring structure 114 may be electrically connected to the lower bonding pads 113 or the lower test pad 115.

The first semiconductor chip SC1 includes a semiconductor device. For example, the first semiconductor chip SC1 may include a logic semiconductor device, a memory semiconductor device, an image sensor device, or a modem semiconductor device. The semiconductor device of the first semiconductor chip SC1 may be provided between the substrate SUB and the wiring structure 114. The semiconductor device may be electrically connected to the conductive structure of the wiring structure 114.

The substrate SUB may be provided on the wiring structure 114. The substrate SUB may be a semiconductor substrate, a dielectric substrate, a silicon-on-insulator (SOI) substrate, or a germanium-on-insulator (GOI) substrate. The upper dielectric layer 117 may be provided on the substrate SUB.

The through vias 116 may penetrate the substrate SUB. The through vias 116 may extend in the third direction D3. The through vias 116 may be electrically connected to the conductive structure of the wiring structure 114. The through vias 116 may be connected to the upper bonding pads 118 or the upper test pad 119. The through vias 116 may include a conductive material.

Similar to the first semiconductor chip SC1, each of the second and third semiconductor chips SC2 and SC3 includes a semiconductor device, a lower dielectric layer 111, lower bonding pads 113, a lower test pad 115, a wiring structure 114, a substrate SUB, through vias 116, an upper dielectric layer 117, upper bonding pads 118, and an upper test pad 119.

The second semiconductor chip SC2 may be hybrid-bonded to the first semiconductor chip SC1. The lower bonding pads 113 of the second semiconductor chip SC2 may be in contact with the upper bonding pads 118 of the first semiconductor chip SC1. The lower bonding pads 113 of the second semiconductor chip SC2 may overlap in the third direction D3 with the upper bonding pads 118 of the first semiconductor chip SC1. The lower test pad 115 of the second semiconductor chip SC2 may be in contact with the upper test pad 119 of the first semiconductor chip SC1. The lower test pad 115 of the second semiconductor chip SC2 may overlap in the third direction D3 with the upper test pad 119 of the first semiconductor chip SC1. The lower dielectric layer 111 of the second semiconductor chip SC2 may be in contact with the upper dielectric layer 117 of the first semiconductor chip SC1.

The third semiconductor chip SC3 may be hybrid-bonded to the second semiconductor chip SC2. The lower bonding pads 113 of the third semiconductor chip SC3 may be in contact with the upper bonding pads 118 of the second semiconductor chip SC2. The lower test pad 115 of the third semiconductor chip SC3 may be in contact with the upper test pad 119 of the second semiconductor chip SC2. The lower dielectric layer 111 of the third semiconductor chip SC3 may be in contact with the upper dielectric layer 117 of the second semiconductor chip SC2.

The fourth semiconductor chip SC4 includes a semiconductor device, a lower dielectric layer 111, lower bonding pads 113, a lower test pad 115, a wiring structure 114, and a substrate SUB. The semiconductor device, the lower dielectric layer 111, the lower bonding pads 113, the lower test pad 115, the wiring structure 114, and the substrate SUB of the fourth semiconductor chip SC4 may be similar to the semiconductor device, the lower dielectric layer 111, the lower bonding pads 113, the lower test pad 115, the wiring structure 114, and the substrate SUB of the first semiconductor chip SC1, respectively.

The fourth semiconductor chip SC4 may be hybrid-bonded to the third semiconductor chip SC3. The lower bonding pads 113 of the fourth semiconductor chip SC4 may be in contact with the upper bonding pads 118 of the third semiconductor chip SC3. The lower test pad 115 of the fourth semiconductor chip SC4 may be in contact with the upper test pad 119 of the third semiconductor chip SC3. The lower dielectric layer 111 of the fourth semiconductor chip SC4 may be in contact with the upper dielectric layer 117 of the third semiconductor chip SC3.

The base structure BS may have a width greater than those of the first, second, third, and fourth semiconductor chips SC1, SC2, SC3, and SC4. In some implementations, the base structure BS includes a semiconductor device, a lower dielectric layer 111, a wiring structure 114, a substrate SUB, through vias 116, an upper dielectric layer 117, upper bonding pads 118, and an upper test pad 119. The semiconductor device, the lower dielectric layer 111, the wiring structure 114, the substrate SUB, the through vias 116, the upper dielectric layer 117, the upper bonding pads 118, and the upper test pad 119 of the base structure BS may be similar to the semiconductor device, the lower dielectric layer 111, the wiring structure 114, the substrate SUB, the through vias 116, the upper dielectric layer 117, the upper bonding pads 118, and the upper test pad 119 of the first semiconductor chip SC1, respectively.

The base structure BS further includes connection pads 112. The connection pads 112 may be disposed in the lower dielectric layer 111. The connection pads 112 may electrically connect the conductive structure of the wiring structure 114 to the terminal TE. The connection pads 112 may include a conductive material.

In some implementations, the base structure BS may be a redistribution substrate or a printed circuit board on which no semiconductor device is included.

Referring to FIGS. 1B, 1C, 1D, and 1E, the upper test pad 119 of the first semiconductor chip SC1 includes a first overlapping portion OV1 that overlaps in the third direction D3 with the lower test pad 115 of the second semiconductor chip SC2, and also includes second overlapping portions OV2 that do not overlap in the third direction D3 with the lower test pad 115 of the second semiconductor chip SC2. The second overlapping portions OV2 may overlap in the third direction D3 with the lower dielectric layer 111 of the second semiconductor chip SC2.

The lower test pad 115 of the second semiconductor chip SC2 includes a third overlapping portion OV3 that overlaps in the third direction D3 with the upper test pad 119 of the first semiconductor chip SC1, and also includes fourth overlapping portions OV4 that do not overlap in the third direction D3 with the upper test pad 119 of the first semiconductor chip SC1. The fourth overlapping portions OV4 may overlap in the third direction D3 with the upper dielectric layer 117 of the first semiconductor chip SC1.

The first overlapping portion OV1 may be disposed between the second overlapping portions OV2. The second overlapping portions OV2 may be spaced apart from each other in the first direction D1 across the first overlapping portion OV1. The first overlapping portion OV1 may overlap in the third direction D3 with the third overlapping portion OV3. A top surface OV1_T of the first overlapping portion OV1 may be in contact with a bottom surface OV3_B of the third overlapping portion OV3. A top surface OV2_T of the second overlapping portion OV2 may be in contact with a bottom surface of the lower dielectric layer 111 of the second semiconductor chip SC2.

The third overlapping portion OV3 may be disposed between the fourth overlapping portions OV4. The fourth overlapping portions OV4 may be spaced apart from each other in the third direction D3 across the third overlapping portion OV3. A bottom surface of the fourth overlapping portions OV4 may be in contact with a top surface of the upper dielectric layer 117 of the first semiconductor chip SC1.

The second overlapping portions OV2 may not overlap the fourth overlapping portions OV4. An area of the top surface OV1_T of the first overlapping portion OV1 and an area of the bottom surface OV3_B of the third overlapping portion OV3 may be, for example, equal to or less than about 50% of an area of a top surface of the upper bonding pads 118 included in the first semiconductor chip SC1 or an area of a bottom surface of the lower bonding pads 113 included in the second semiconductor chip SC2.

A contact area between the upper test pad 119 of the first semiconductor chip SC1 and the lower test pad 115 of the second semiconductor chip SC2 may be set to produce a relatively large change of resistance caused by fabrication errors. The area of the top surface OV1_T of the first overlapping portion OV1 may be, for example, about 20% of an area of a top surface of the upper test pad 119 included in the first semiconductor chip SC1. The area of the bottom surface OV3_B of the third overlapping portion OV3 may be, for example, about 20% of an area of a top surface of the lower test pad 115 included in the second semiconductor chip SC2.

The first overlapping portion OV1 includes a first sidewall OV1_S1 and a second sidewall OV1_S2 that are opposite to each other. Each second overlapping portion OV2 includes a first sidewall OV2_S1, a second sidewall OV2_S2 opposite to the first sidewall OV2_S2, and a third sidewall OV2_S3 between the first sidewall OV2_S1 and the second sidewall OV2_S2. The first and second sidewalls OV1_S1 and OV2_S2 of the first overlapping portion OV1 may be parallel to the first direction D1, and likewise the first and second sidewalls OV2_S1 and OV2_S2 of the second overlapping portions OV2 may be parallel to the first direction D1. The third sidewall OV2_S3 of the second overlapping portions OV2 may be parallel to the second direction D2.

The first sidewall OV1_S1 of the first overlapping portion OV1 may be coplanar with the first sidewalls OV2_S1 of the second overlapping portions OV2. The first sidewall OV1_S1 of the first overlapping portion OV1 may be connected to the first sidewalls OV2_S1 of the second overlapping portions OV2. The first sidewall OV1_S1 of the first overlapping portion OV1 may be disposed between the first sidewalls OV2_S1 of the second overlapping portions OV2. The second sidewall OV1_S2 of the first overlapping portion OV1 may be coplanar with the second sidewalls OV2_S2 of the second overlapping portions OV2. The third sidewalls OV2_S3 of the second overlapping portions OV2 may be parallel to each other.

Each second overlapping portion OV2 further includes connection surfaces CS1. The connection surface CS1 may connect one of the first sidewall OV2_S1 and the second sidewall OV2_S2 to the third sidewall OV2_S3. The connection surface CS1 may be curved when viewed in plan as shown in FIG. 1E. In some implementations, the second overlapping portion OV2 may be configured such that one of the first sidewall OV2_S1 and the second sidewall OV2_S2 to the third sidewall OV2_S3 without the connection surface CS1.

The third overlapping portion OV3 includes a first sidewall OV3_S1 and a second sidewall OV3_S2 that are opposite to each other. Each fourth overlapping portion OV4 includes a first sidewall OV4_S1, a second sidewall OV4_S2 opposite to the first sidewall OV4_S1, and a third sidewall OV4_S3 between the first sidewall OV4_S1 and the second sidewall OV4_S2. The first and second sidewalls OV3_S1 and OV3_S2 of the third overlapping portion OV3 may be parallel to the second direction D2, and likewise the first and second sidewalls OV4_S1 and OV4_S2 of the fourth overlapping portions OV4 may be parallel to the second direction D2. The third sidewall OV4_S3 of the fourth overlapping portions OV4 may be parallel to the first direction D1.

The first sidewall OV3_S1 of the third overlapping portion OV3 may be coplanar with the first sidewalls OV4_S1 of the fourth overlapping portions OV4. The second sidewall OV3_S2 of the third overlapping portion OV3 may be coplanar with the second sidewalls OV4_S2 of the fourth overlapping portions OV4.

The fourth overlapping portion OV4 further include connection surfaces CS2. The connection surface CS2 may connect one of the first sidewall OV4_S1 and the second sidewall OV4_S2 to the third sidewall OV4_S3. The connection surface CS2 may be curved when viewed in plan as shown in FIG. 1E. In some implementations, the fourth overlapping portions OV4 may be configured such that one of the first sidewall OV4_S1 and the second sidewall OV4_S2 to the third sidewall OV4_S3 without the connection surface CS2.

The upper test pad 119 of the first semiconductor chip SC1 includes first long sidewalls LS1 that are parallel to each other, and also includes first short sidewalls SS1 that are parallel to each other. The first long sidewalls LS1 may be sidewalls that are opposite to each other. The first short sidewalls SS1 may be sidewalls that are opposite to each other. The lower test pad 115 of the second semiconductor chip SC2 includes second long sidewalls LS2 that are parallel to each other, and also includes second short sidewalls SS2 that are parallel to each other. The second long sidewalls LS2 may be sidewalls that are opposite to each other. The second short sidewalls SS2 may be sidewalls that are opposite to each other.

The first long sidewalls LS1 and the second long sidewalls LS2 may be longer than the first short sidewalls SS1 and the second short sidewalls SS2. The first long sidewalls LS1 and the second short sidewalls SS2 may extend in the first direction D1. The second long sidewalls LS2 and the first short sidewalls SS1 may extend in the second direction D2. The first long sidewalls LS1 includes the first sidewalls OV1_S1 and OV2_S1 or the second sidewalls OV1_S2 and OV2_S2 of the first and second overlapping portions OV1 and OV2. The second long sidewalls LS2 includes the first sidewalls OV3_S1 and OV4_S1 or the second sidewalls OV3_S2 and OV4_S2 of the third and fourth overlapping portions OV3 and OV4. The first short sidewall SS1 may be the third sidewall OV2_S3 of the second overlapping portion OV2. The second short sidewall SS2 may be the third sidewall OV4_S3 of the fourth overlapping portions OV4.

A first long sidewall LS1 and a first short sidewall SS1 may be connected through the connection surface CS1 of the second overlapping portion OV2. In some implementations, the first long sidewall LS1 and the first short sidewall SS1 may be directly connected without the connection surface CS1. The second long sidewall LS2 and the second short sidewall SS2 may be connected through the connection surface CS2 of the fourth overlapping portions OV4. In some implementations, the second long sidewall LS2 and the second short sidewall SS2 may be directly connected without the connection surface CS2.

The first long sidewalls LS1 and the second long sidewalls LS2 may overlap each other in the third direction D3. The first long sidewalls LS1 may overlap in the third direction D3 with the lower test pad 115 of the second semiconductor chip SC2. The second long sidewalls LS2 may overlap in the third direction D3 with the upper test pad 119 of the first semiconductor chip SC1. The first sidewalls SS1 and the second sidewalls SS2 may not overlap each other in the third direction D3. The first sidewalls SS1 may not overlap in the third direction D3 with the lower test pad 115 of the second semiconductor chip SC2. The second sidewalls SS2 may not overlap in the third direction D3 with the upper test pad 119 of the first semiconductor chip SC1.

A distance in the second direction D2 between the first long sidewalls LS1 and a distance in the first direction D1 between the second long sidewalls LS2 may be less than a distance in the first direction D1 between the first short sidewalls SS1 and a distance in the second direction D2 between the second short sidewalls SS2.

The first semiconductor chip SC1 includes two first sidewalls SC1_S1 that extend in the first direction D1 and two second sidewalls SC1_S2 that extend in the second direction D2. The first sidewalls SC1_S1 of the first semiconductor chip SC1 may be connected to the two second sidewalls SC1_S2 of the first semiconductor chip SC1.

The first long sidewalls LS1 and the second short sidewalls SS2 may be parallel to the first sidewalls SC1_S1 and SC2_S1 of the first and second semiconductor chips SC1 and SC2. The second long sidewalls LS2 and the first short sidewalls SS1 may be parallel to the second sidewalls SC1_S2 and SC2_S2 of the first and second semiconductor chips SC1 and SC2.

In some implementations, a length of the first and second sidewalls OV1_S1 and OV1_S2 of the first overlapping portion OV1 may be less than a length of the first and second sidewalls OV2_S1 and OV2_S2 of the second overlapping portions OV2. In some implementations, a length of the first and second sidewalls OV3_S1 and OV3_S2 of the third overlapping portion OV3 may be less than a length of the first and second sidewalls OV4_S1 and OV4_S2 of the fourth overlapping portions OV4.

The upper test pad 119 of the first semiconductor chip SC1 may have a first length L1 in the first direction D1 and a second length L2 in the second direction D2. The first length L1 may be a distance in the first direction D1 between the first short sidewalls SS1. The second length L2 may be a distance in the second direction D2 between the first long sidewalls LS1.

The lower test pad 115 of the second semiconductor chip SC2 may have a third length L3 in the second direction D2 and a fourth length L4 in the first direction D1. The third length L3 may be a distance in the second direction D2 between the second short sidewalls SS2. The fourth length L4 may be a distance in the first direction D1 between the second long sidewalls LS2.

The first length L1 and the third length L3 may be greater than the second length L2 and the fourth length L4. The second length L2 and the fourth length L4 may be less than a diameter of the upper bonding pads 118 and a diameter of the lower bonding pads 113. Therefore, sizes (e.g., planar areas) of the upper test pad 119 and the lower test pad 115 may be less than sizes of the upper bonding pads 118 and the lower bonding pads 113.

The upper bonding pads 118 of the first semiconductor chip SC1 may surround the upper test pad 119 of the first semiconductor chip SC1. A distance between the upper bonding pads 118 of the first semiconductor chip SC1 and the first and second sidewalls SC1_S1 and SC1_S2 of the first semiconductor chip SC1 may be less than a distance between the upper test pad 119 of the first semiconductor chip SC1 and the first and second sidewalls SC1_S1 and SC2_S2 of the first semiconductor chip SC1.

The lower bonding pads 113 of the second semiconductor chip SC2 may surround the lower test pad 115 of the second semiconductor chip SC2. A distance between the lower bonding pads 113 of the second semiconductor chip SC2 and the first and second sidewalls SC2_S1 and SC2_S2 of the second semiconductor chip SC2 may be less than a distance between the lower test pad 115 of the second semiconductor chip SC2 and the first and second sidewalls SC2_S1 and SC2_S2 of the second semiconductor chip SC2.

A bonding structure between the upper test pad 119 of the second semiconductor chip SC2 and the lower test pad 115 of the third semiconductor chip SC3, a bonding structure between the upper test pad 119 of the third semiconductor chip SC3 and the lower test pad 115 of the fourth semiconductor chip SC4, and a bonding structure between the upper test pad 119 of the base structure BS and the lower test pad 115 of the first semiconductor chip SC1 may be similar to a bonding structure between the upper test pad 119 of the first semiconductor chip SC1 and the lower test pad 115 of the second semiconductor chip SC2.

In a semiconductor package according to some implementations, the upper test pad 119 that extends in the first direction D1 and the lower test pad 115 that extends in the second direction D2 may be bonded while crossing each other. Therefore, even when misalignment occurs in the first direction D1 in a bonding process of the upper test pad 119 and the lower test pad 115, the second direction D2, or a rotational direction, a contact area between the upper test pad 119 and the lower test pad 115 may be constant, and a resistance between the upper test pad 119 and the lower test pad 115 may be less affected by the misalignment in the bonding process.

Therefore, the resistance between the upper test pad 119 and the lower test pad 115 may be measured to easily evaluate diffusivity or voids at a bonding interface between the upper test pad 119 and the lower test pad 115 and to easily estimate quality of bonding between the upper bonding pads 118 and the lower bonding pads 113.

In a semiconductor package according to some implementations, as sizes of the upper test pad 119 and the lower test pad 115 is less than sizes of the upper bonding pads 118 and the lower bonding pads 113, it may be possible to freely place the upper test pad 119 and the lower test pad 115 and to increase the degree of freedom of design for semiconductor chips.

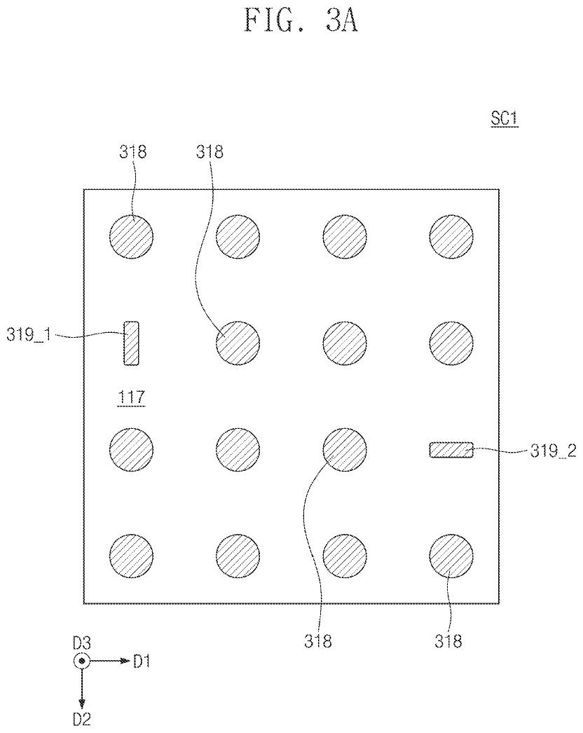

FIGS. 2A and 2B illustrate plan views of semiconductor chips viewed from a bonding section between semiconductor chips of a semiconductor package according to some implementations. Except that discussed below, a semiconductor package of FIGS. 2A and 2B may be similar to the semiconductor package of FIGS. 1A to 1E.

Referring to FIGS. 2A and 2B, an upper test pad 219 of the first semiconductor chip SC1 may extend in a fourth direction D4. The fourth direction D4 may intersect the first, second, and third directions D1, D2, and D3. For example, the fourth direction D4 may be a horizontal direction perpendicular to the third direction D3.

A lower test pad 215 of the second semiconductor chip SC2 may extend in a fifth direction D5. The fifth direction D5 may intersect the first, second, third, and fourth directions D1, D2, D3, and D4. For example, the fifth direction D5 may be a horizontal direction perpendicular to the third direction D3.

The upper test pad 219 and the lower test pad 215 of the first and second semiconductor chips SC1 and SC2 may be bonded while crossing each other.

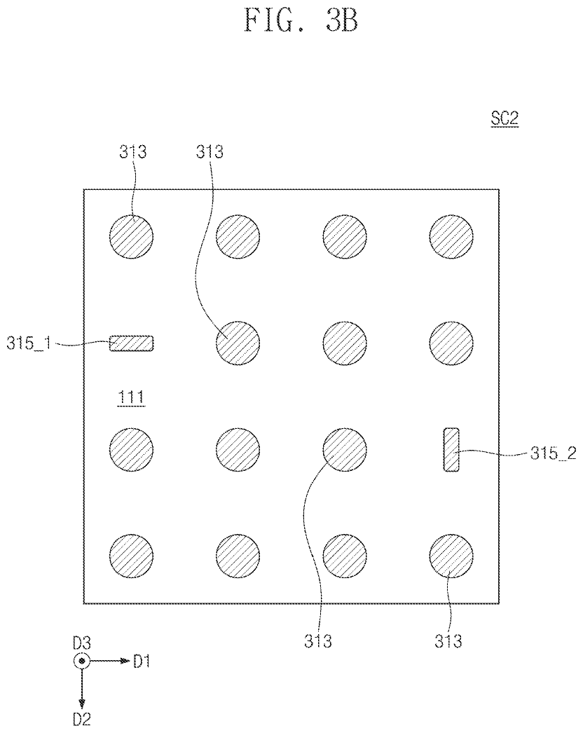

FIGS. 3A and 3B illustrate plan views of semiconductor chips viewed from a bonding section between semiconductor chips of a semiconductor package according to some implementations. Other than those discussed below, a semiconductor package of FIGS. 3A and 3B may be similar to the semiconductor package of FIGS. 1A to 1E.

Referring to FIGS. 3A and 3B, the first semiconductor chip SC1 includes a first upper test pad 319_1 and a second upper test pad 319_2. The first upper test pad 319_1 may extend in the second direction D2. The second upper test pad 3192 may extend in the first direction D1. The first semiconductor chip SC1 includes upper bonding pads 318 between the first and second upper test pads 319_1 and 319_2.

The second semiconductor chip SC2 includes a first lower test pad 315_1 and a second lower test pad 315_2. The first lower test pad 3151 may extend in the first direction D1. The second lower test pad 315_2 may extend in the second direction D2. The first lower test pad 315_1 may be bonded to the first upper test pad 3191. The second lower test pad 3152 may be bonded to the second upper test pad 319_2. The second semiconductor chip SC2 includes lower bonding pads 313 between the first and second lower test pads 315_1 and 315_2.

In a semiconductor package according to some implementations, as the test pads 315_1, 3152, 319_1, and 319_2 have relatively small sizes, the test pads 315_1, 315_2, 319_1, and 3192 may not need to be disposed only a specific region, and the bonding pads 313 and 318 may be placed between the test pads 315_1, 315_2, 319_1, and 319_2, which may result in an increase in the degree of freedom of design for semiconductor chips.

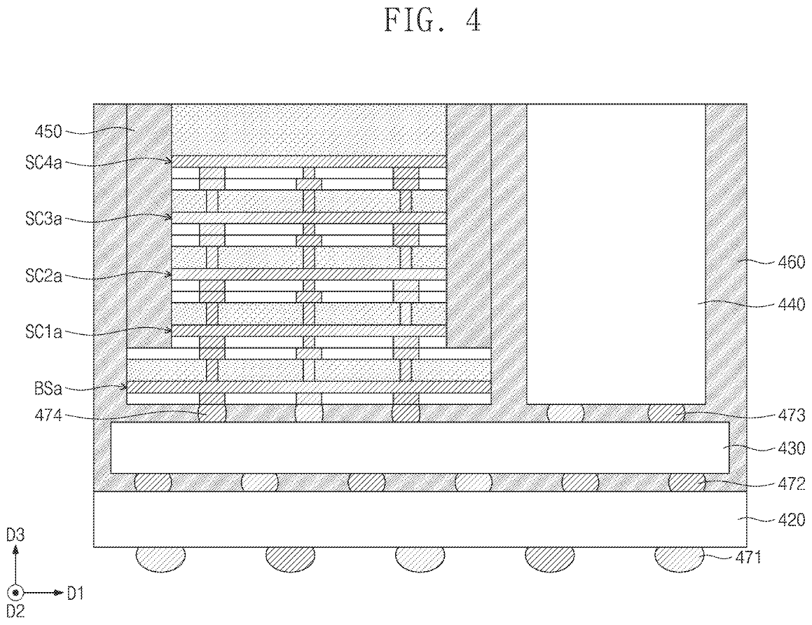

FIG. 4 illustrates a cross-sectional view showing a semiconductor package according to some implementations.

Referring to FIG. 4, a semiconductor package includes a package substrate 420. For example, the package substrate 420 may be a printed circuit board (PCB). First terminals 471 may be provided which are electrically connected to the package substrate 420. The semiconductor package may be mounted through the first terminals 471 on an external apparatus (e.g., mainboard).

An interposer 430 may be provided on the package substrate 420. Second terminals 472 may be provided which electrically connect the package substrate 420 to the interposer 430. The second terminals 472 may be provided between the package substrate 420 and the interposer 430.

A processor chip 440 may be provided on the interposer 430. For example, the processor chip 440 may be a graphic processing unit (GPU) or a central processing unit (CPU). Third terminals 473 may be provided which electrically connect the processor chip 440 to the interposer 430. The third terminals 473 may be provided between the processor chip 440 and the interposer 430.

The interposer 430 may be provided thereon with a base structure BSa and first, second, third, and fourth semiconductor chips SC1a, SC2a, SC3a, and SC4a. The base structure BSa and the first, second, third, and fourth semiconductor chips SC1a, SC2a, SC3a, and SC4a may be similar to the base structure BS and the first, second, third, and fourth semiconductor chips SC1, SC2, SC3, and SC4, respectively, of FIGS. 1A to 1E.

The base structure BSa and the first, second, third, and fourth semiconductor chips SC1a, SC2a, SC3a, and SC4a may be spaced apart in the first direction D1 from the processor chip 440. Fourth terminals 474 may be provided which electrically connect the base structure BSa to the interposer 430. The fourth terminals 474 may be provided between the base structure BSa and the interposer 430. A first molding layer 450 may be provided to surround the base structures BSa and the first, second, third, and fourth semiconductor chips SC1a, SC2a, SC3a, and SC4a.

The package substrate 420 may be provided thereon with a second molding layer 460 that surrounds the interposer 430, the processor chip 440, the base structure BSa, and the first, second, third, and fourth semiconductor chips SC1a, SC2a, SC3a, and SC4a.

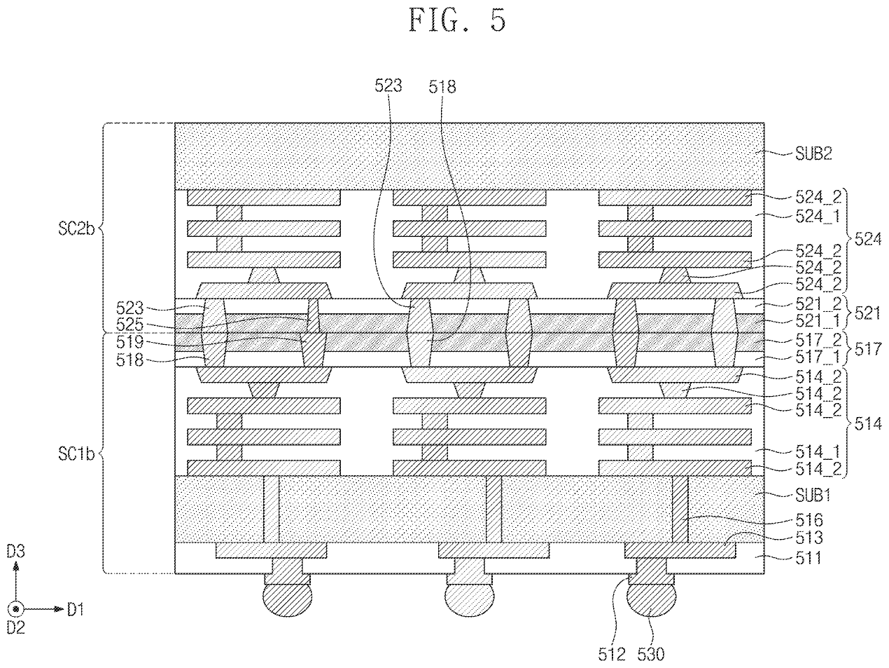

FIG. 5 illustrates a cross-sectional view showing a semiconductor package according to some implementations.

Referring to FIG. 5, a semiconductor package includes a first semiconductor chip SC1b, a second semiconductor chip SC2b, and terminals 530.

The second semiconductor chip SC2b may be provided on the first semiconductor chip SC1b. A hybrid bonding may be achieved between the first semiconductor chip SC1b and the second semiconductor chip SC2b. The terminals 530 may be connected to the first semiconductor chip SC1b.

The first semiconductor chip SC1b includes a first lower dielectric layer 511, connection pads 512, lower conductive lines 513, a first substrate SUB1, through vias 516, a first wiring structure 514, an upper dielectric layer 517, upper bonding pads 518, and an upper test pad 519.

The first lower dielectric layer 511 may surround the connection pads 512 and the lower conductive lines 513. The connection pad 512 may be connected to the terminal 530, and the lower conductive line 513 may be connected to the connection pad 512. The connection pad 512 and the lower conductive line 513 may include a conductive material.

The first substrate SUB1 may be provided on the first lower dielectric layer 511. The through via 516 may penetrate the first substrate SUB1 to be connected to the lower conductive line 513.

The first wiring structure 514 may be provided on the first substrate SUB1. A semiconductor device may be provided between the first substrate SUB1 and the first wiring structure 514. The first wiring structure 514 includes a first dielectric layer 514_1 and first conductive structures 514_2. The first conductive structure 5142 may be a conductive line, a conductive pad, or a conductive via. The first conductive structures 514_2 may electrically connect the through via 516 to the upper bonding pad 518 or the upper test pad 519.

The first dielectric layer 5141 may include a dielectric material. For example, the first dielectric layer 5141 may include tetraethylorthosilicate (TEOS). In some implementations, the first dielectric layer 514_1 may be a multiple layer including a plurality of dielectric layers.

The upper dielectric layer 517 may be provided in the first wiring structure 514. The upper dielectric layer 517 includes a first layer 517_1 on the first wiring structure 514 and a second layer 517_2 on the first layer 5171. The first layer 517_1 and the second layer 5172 of the upper dielectric layer 517 may include different dielectric materials. For example, the first layer 517_1 of the upper dielectric layer 517 may include tetraethylorthosilicate (TEOS), and the second layer 517_2 of the upper dielectric layer 517 may include silicon carbonitride (SiCN).

The upper bonding pads 518 and the upper test pad 519 may penetrate in the third direction D3 through the first layer 517_1 and the second layer 517_2 of the upper dielectric layer 517. The upper bonding pads 518 and the upper test pad 519 may each have a width that increases with increasing level.

The second semiconductor chip SC2b includes a second lower dielectric layer 521, lower bonding pads 523, a lower test pad 525, a second wiring structure 524, and a second substrate SUB2.

The second lower dielectric layer 521 may be bonded to the upper dielectric layer 517. The second lower dielectric layer 521 includes a first layer 521_1 in contact with the second layer 517_2 of the upper dielectric layer 517, and also includes a second layer 5212 on the first layer 521_1. The first layer 521_1 and the second layer 521_2 of the second lower dielectric layer 521 may include different dielectric materials. The first layer 521_1 of the second lower dielectric layer 521 may include the same dielectric material as that of the second layer 5172 of the upper dielectric layer 517. The second layer 521_2 of the second lower dielectric layer 521 may include the same dielectric material as that of the first layer 517_1 of the upper dielectric layer 517. For example, the second layer 5212 of the second lower dielectric layer 521 may include tetraethylorthosilicate (TEOS), and the first layer 5211 of the second lower dielectric layer 521 may include silicon carbonitride (SiCN).

The lower bonding pads 523 and the lower test pad 525 may penetrate in the third direction D3 through the first layer 521_1 and the second layer 521_2 of the second lower dielectric layer 521. The lower bonding pads 523 and the lower test pad 525 may each have a width that decreases with increasing level. The lower bonding pad 523 and the upper bonding pad 518 may be bonded to each other. The lower test pad 515 may be bonded to the upper test pad 519.

The upper test pad 519 may have a length in the first direction D1 greater than a length in the second direction D2, and the lower test pad 515 may have a length in the second direction D2 greater than a length in the first direction D1. Therefore, the lower test pad 515 and the upper test pad 519 may be bonded while crossing each other.

The second wiring structure 524 may be provided on the second lower dielectric layer 521. The second wiring structure 524 includes a second dielectric layer 524_1 and second conductive structures 524_2. The second conductive structure 5242 may be a conductive line, a conductive pad, or a conductive via. The second conductive structures 5242 may be electrically connected to the lower bonding pad 523 or the lower test pad 525.

The second dielectric layer 5241 may include the same dielectric material as that of the first dielectric layer 514_1. In some implementations, the second dielectric layer 524_1 may be a multiple layer including a plurality of dielectric layers.

The second substrate SUB2 may be provided on the second wiring structure 524. A semiconductor device may be provided between the second wiring structure 524 and the second substrate SUB2.

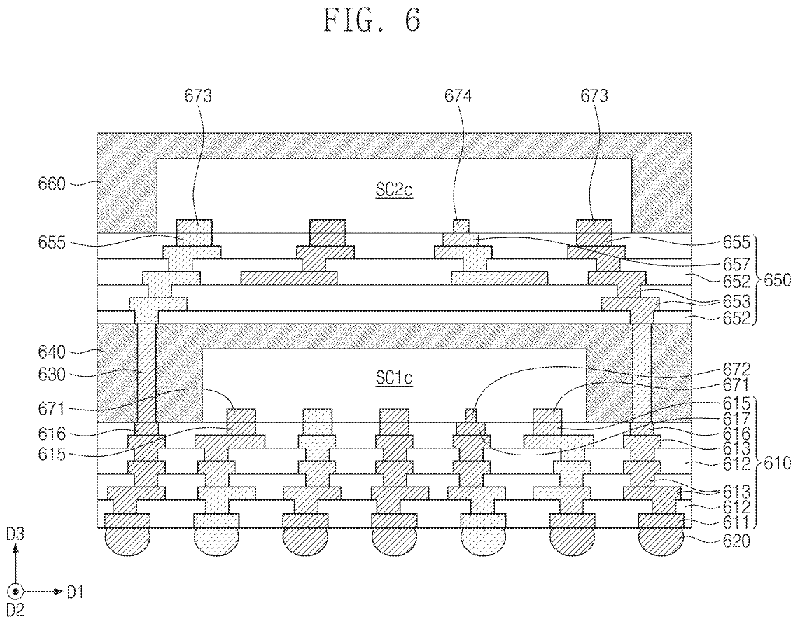

FIG. 6 illustrates a cross-sectional view showing a semiconductor package according to some implementations.

Referring to FIG. 6, a semiconductor package includes a first redistribution substrate 610, terminals 620, a first semiconductor chip SC1c, a first molding layer 640, connection vias 630, a second redistribution substrate 650, a second semiconductor chip SC2c, and a second molding layer 660.

The first redistribution substrate 610 includes under-bump patterns 611, first photosensitive dielectric layers 612, first redistribution patterns 613, first bonding pads 615, a first test pad 617, and connection patterns 616.

The first photosensitive dielectric layers 612 may include a photo-imageable dielectric material. The photo-imageable dielectric material may include, for example, at least one selected from photosensitive polyimide, polybenzoxazole, phenolic polymers, and benzocyclobutene polymers.

The under-bump patterns 611 may be disposed in a lowermost one of the first photosensitive dielectric layers 612. The terminal 620 may be connected to the under-bump pattern 611. The terminal 620 and the under-bump pattern 611 may include a conductive material.

The first redistribution patterns 613 may be provided in the first photosensitive dielectric layers 612. The first redistribution patterns 613 may be electrically connected to the under-bump pattern 611. The first redistribution patterns 613 may include a conductive material. The first redistribution patterns 613 may include a via portion that extends in a vertical direction and a wiring portion that extends in a horizontal direction.

The first bonding pads 615, the connection patterns 616, and the first test pad 617 may be disposed in an uppermost one of the first photosensitive dielectric layers 612. The first bonding pads 615, the connection patterns 616, and the first test pad 617 may include a conductive material.

The first semiconductor chip SC1c may be provided on the first redistribution substrate 610. The first semiconductor chip SC1c includes a second bonding pad 671 bonded to the first bonding pad 615 and a second test pad 672 bonded to the first test pad 617. The first test pad 617 may have a length in the first direction D1 greater than a length in the second direction D2, and the second test pad 672 may have a length in the second direction D2 greater than a length in the first direction D1. Therefore, the first and second test pads 617 and 672 may be bonded while crossing each other.

The first redistribution substrate 610 may be provided thereon with the first molding layer 640 that surrounds the first semiconductor chip SC1c. The connection vias 630 may penetrate the first molding layer 640. The connection vias 630 may be connected to the connection pattern 616. The connection vias 630 may include a conductive material.

The second redistribution substrate 650 may be provided on the first molding layer 640. The second redistribution substrate 650 includes second photosensitive dielectric layers 652, second redistribution patterns 653, third bonding pads 655, and a third test pad 657.

The second photosensitive dielectric layers 652 may include a photo-imageable dielectric material. The second redistribution patterns 653 may be provided in the second photosensitive dielectric layers 652. The second redistribution patterns 653 may be electrically connected to the connection vias 630. The second redistribution patterns 653 may include a conductive material. The second redistribution patterns 653 may include a via portion that extends in a vertical direction and a wiring portion that extends in a horizontal direction.

The third bonding pads 655 and the third test pad 657 may be disposed in an uppermost one of the second photosensitive dielectric layers 652. The third bonding pads 655 and the third test pad 657 may include a conductive material.

The second semiconductor chip SC2c may be provided on the second redistribution substrate 650. The second semiconductor chip SC2c includes a fourth bonding pad 673 bonded to the third bonding pad 655 and a fourth test pad 674 bonded to the third test pad 657. The third test pad 657 may have a length in the first direction D1 greater than a length in the second direction D2, and the fourth test pad 674 may have a length in the second direction D2 greater than a length in the first direction D1. Therefore, the first and second test pads 657 and 674 may be bonded while crossing each other.

The second redistribution substrate 650 may be provided thereon with the second molding layer 660 that surrounds the second semiconductor chip SC2c.

In a semiconductor package according to some implementations of the present disclosure, test pads may be included which are bonded while crossing each other, and thus it may be possible to easily evaluate bonding quality of bonding pads.

In a semiconductor package according to some implementations of the present disclosure, test pads may have relatively small sizes, and therefore, there may be an increase in the degree of freedom of design for semiconductor chips.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

Although the present disclosure has been described in connection with the some implementations illustrated in the accompanying drawings, it will be understood by one of ordinary skill in the art that variations in form and detail may be made therein without departing from the spirit and essential feature of the present disclosure. The above disclosed implementations should thus be considered illustrative and not restrictive.

What is claimed is:

1. A semiconductor package, comprising:
a first semiconductor chip; and
a second semiconductor chip on the first semiconductor chip,
wherein the first semiconductor chip includes:
an upper bonding pad;
an upper test pad; and
an upper dielectric layer that surrounds the upper bonding pad and the upper test pad,
wherein the second semiconductor chip includes:
a lower bonding pad in contact with the upper bonding pad;
a lower test pad in contact with the upper test pad; and
a lower dielectric layer that surrounds the lower bonding pad and the lower test pad,
wherein the upper test pad includes:
a first overlapping portion that overlaps the lower test pad; and
a plurality of second overlapping portions that overlap the lower dielectric layer,
wherein the first overlapping portion is between the plurality of second overlapping portions,
wherein the lower test pad includes:
a third overlapping portion that overlaps the first overlapping portion of the upper test pad; and
a plurality of fourth overlapping portions that overlap the upper dielectric layer,
wherein the third overlapping portion is between the plurality of fourth overlapping portions.

2. The semiconductor package of claim 1, wherein the plurality of second overlapping portions are offset from the plurality of fourth overlapping portions.

3. The semiconductor package of claim 1, wherein
the upper test pad includes a plurality of first long sidewalls that extend in parallel to each other and a plurality of first short sidewalls that extend in parallel to each other,
the lower test pad includes a plurality of second long sidewalls that extend in parallel to each other and a plurality of second short sidewalls that extend in parallel to each other,
each first long sidewall of the plurality of first long sidewalls is longer than each first short sidewall of the plurality of first short sidewalls, and
each second long sidewall of the plurality of second long sidewalls is longer than each second short sidewall of the plurality of second short sidewalls.

4. The semiconductor package of claim 3, wherein the plurality of first long sidewalls overlap the plurality of second long sidewalls.

5. The semiconductor package of claim 3, wherein a distance between adjacent first long sidewalls is less than a distance between adjacent first short sidewalls, and a distance between adjacent second long sidewalls is less than a distance between adjacent second short sidewalls.

6. The semiconductor package of claim 1, wherein
the upper test pad has a first length in a first direction and a second length in a second direction that intersects the first direction,
the lower test pad has a third length in the first direction and a fourth length in the second direction,
the first length is greater than the second length and the third length, and
the fourth length is greater than the second length and the third length.

7. The semiconductor package of claim 1, wherein an area of a top surface of the first overlapping portion is equal to or less than about 50% of an area of a top surface of the upper bonding pad.

8. The semiconductor package of claim 1, wherein
the first semiconductor chip includes a plurality of upper bonding pads, and
the upper test pad is surrounded by the plurality of upper bonding pads.

9. The semiconductor package of claim 1, wherein
a top surface of the first overlapping portion is in contact with a bottom surface of the third overlapping portion, and
a top surface of each of the plurality of second overlapping portions is in contact with a bottom surface of the lower dielectric layer.

10. A semiconductor package, comprising:
a first semiconductor chip; and
a second semiconductor chip on the first semiconductor chip,
wherein the first semiconductor chip includes an upper bonding pad and an upper test pad,
wherein the second semiconductor chip includes:
a lower bonding pad in contact with the upper bonding pad; and
a lower test pad in contact with the upper test pad,
wherein the upper test pad includes:
a plurality of first long sidewalls that extend in parallel to each other; and
a plurality of first short sidewalls that extend in parallel to each other,
wherein the lower test pad includes:
a plurality of second long sidewalls that extend in parallel to each other; and
a plurality of second short sidewalls that extend in parallel to each other,
wherein the plurality of first short sidewalls are shorter than the plurality of first long sidewalls, and
wherein the plurality of second short sidewalls are shorter than the plurality of second long sidewalls.

11. The semiconductor package of claim 10, wherein the plurality of first long sidewalls overlap the second long sidewalls.

12. The semiconductor package of claim 10, wherein
the plurality of first short sidewalls are offset from the lower test pad, and
the plurality of second short sidewalls are offset from the upper test pad.

13. The semiconductor package of claim 10,
wherein the upper test pad includes a first upper test pad and a second upper test pad,
wherein the first upper test pad extends in a first direction, and
wherein the second upper test pad extends in a second direction that intersects the first direction.

14. The semiconductor package of claim 13, wherein the upper bonding pad is between the first upper test pad and the second upper test pad.

15. The semiconductor package of claim 13,
wherein the lower test pad includes:
a first lower test pad in contact with the first upper test pad; and
a second lower test pad in contact with the second upper test pad,
wherein the first lower test pad extends in the second direction, and
wherein the second lower test pad extends in the first direction.

16. The semiconductor package of claim 10, wherein the upper test pad further includes a connection surface that connects the first long sidewall to the first short sidewall.

17. The semiconductor package of claim 16, wherein the connection surface is curved.

18. The semiconductor package of claim 10,
wherein the first semiconductor chip includes:
a plurality of first sidewalls that are in parallel to each other; and
a plurality of second sidewalls that are in parallel to each other,
wherein the plurality of first long sidewalls are parallel to the plurality of first sidewalls of the first semiconductor chip, and
wherein the plurality of first short sidewalls are parallel to the plurality of second sidewalls of the first semiconductor chip.

19. A semiconductor package, comprising:
a first semiconductor chip; and
a second semiconductor chip on the first semiconductor chip,
wherein the first semiconductor chip includes:
a first lower dielectric layer;
a first wiring structure on the first lower dielectric layer;
a first substrate on the first wiring structure;
a through via that penetrates the first substrate;
an upper dielectric layer on the first substrate; and
an upper bonding pad and an upper test pad that are surrounded by the upper dielectric layer,
wherein the second semiconductor chip includes:
a lower bonding pad in contact with the upper bonding pad;
a lower test pad in contact with the upper test pad;
a second lower dielectric layer that surrounds the lower bonding pad and the lower test pad;
a second wiring structure on the second lower dielectric layer; and
a second substrate on the second wiring structure,
wherein the upper test pad includes:
a first overlapping portion in contact with the lower test pad; and
a plurality of second overlapping portions in contact with the second lower dielectric layer, and
wherein a sidewall of the first overlapping portion is coplanar with sidewalls of the plurality of second overlapping portions.

20. The semiconductor package of claim 19, wherein the sidewall of the first overlapping portion is shorter than the sidewalls of the plurality of second overlapping portions.
